(19) United States
(12) Patent Application Publication
(10) Pub. No.: US 2014/0105425 A1
(43) Pub. Date: Apr. 17, 2014

(54) Acoustic Amplification Device

(71) Applicants: Colin Chu, Laguna Niguel, CA (US); Robert Bettis Wimbrow, Capistrano Beach, CA (US)

(72) Inventors: Colin Chu, Laguna Niguel, CA (US); Robert Bettis Wimbrow, Capistrano Beach, CA (US)

(21) Appl. No.: 13/651,451

(22) Filed: Oct. 14, 2012

(51) Int. Cl. H03F 99/00

(52) U.S. Cl. 381/120

(57) ABSTRACT

An amplification device amplifies sound waves that emit from a portable electronic device. The portable electronic device joins the amplification device at a horizontal orientation that is efficacious for watching videos in wide screen format. A slot in the amplifying device engages a speaker in the portable electronic device. The amplifying device receives sound waves generated by the speaker at a narrow, speaker receiving end, passes the sound waves through an acoustic channel, and finally emits the sound waves from a wide, amplifying end. Increasing surface area at the wide end of the amplifying device lowers the acoustic impedance, and consequently amplifies the sound waves. The sound waves amplify because acoustic impedance is lowered and matched to the proximate air. A cone-shaped dispersion port positions within the acoustic channel to optimize sound wave dispersion. A housing contains the components and has a sloped surface for supporting chargers.

### CROSS-REFERENCE TO RELATED APPLICATIONS

The present utility patent application claims priority benefit of the U.S. provisional application for patent Ser. No. 61/547,509 entitled “Mobile Device Stand with Integrated Acoustic Amplifying Cone,” filed on Oct. 14, 2011 under 35 U.S.C. §119(e). The contents of this related provisional application are incorporated herein by reference for all purposes to the extent that such subject matter is not inconsistent herewith or limiting hereof.

### FEDERALLY SPONSORED RESEARCH OR DEVELOPMENT

Not applicable.

### REFERENCE TO SEQUENCE LISTING, A TABLE, OR A COMPUTER LISTING APPENDIX

Not applicable.

### COPYRIGHT NOTICE

A portion of the disclosure of this patent document contains material that is subject to copyright protection. The copyright owner has no objection to the facsimile reproduction by anyone of the patent document or patent disclosure as it appears in the Patent and Trademark Office, patent file or records, but otherwise reserves all copyright rights whatsoever.

### FIELD OF THE INVENTION

One or more embodiments of the invention generally relate to acoustic amplification. More particularly, one or more embodiments of the invention relate to acoustic amplification of portable electronic devices.

### BACKGROUND OF THE INVENTION

The following background information may present examples of specific aspects of the prior art (e.g., without limitation, approaches, facts, or common wisdom) that, while expected to be helpful to further educate the reader as to additional aspects of the prior art, is not to be construed as limiting the present invention, or any embodiments thereof, to anything stated or implied therein or inferred thereupon.

The following is an example of a specific aspect in the prior art that, while expected to be helpful to further educate the reader as to additional aspects of the prior art, is not to be construed as limiting the present invention, or any embodiments thereof, to anything stated or implied therein or inferred thereupon. By way of educational background, another aspect of the prior art generally useful to be aware of is that sound is a mechanical wave that is an oscillation of pressure transmitted through a solid, liquid, or gas, composed of frequencies within the range of hearing.

Typically, portable communications devices refer to hand-held or wearable devices. The walkie talkie is a device that is hand-held when in use, and wearable when not in use. Cellular telephones are also carried, or worn, on a belt, or in a pocket.

Typically, video is the technology of electronically capturing, recording, processing, storing, transmitting, and reconstructing a sequence of still images representing scenes in motion. Videos can be displayed on a portable communication device.

In view of the foregoing, it is clear that these traditional techniques are not perfect and leave room for more optimal approaches.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 illustrates a detailed perspective view of an exemplary acoustic amplifying device, in accordance with an embodiment of the present invention;

FIG. 2 illustrates a detailed perspective view of an exemplary acoustic amplifying device joined with an exemplary portable electronic device, in accordance with an embodiment of the present invention;

FIG. 3 illustrates a sectioned side view of an exemplary amplifying portion, in accordance with an embodiment of the present invention;

FIG. 4 illustrates a sectioned top view of an exemplary acoustic amplifying device, in accordance with an embodiment of the present invention;

FIG. 5 illustrates a side view of an exemplary acoustic amplifying device, in accordance with an embodiment of the present invention; and

FIG. 6 illustrates a bottom view of an exemplary mounting surface, in accordance with an embodiment of the present invention.

Unless otherwise indicated illustrations in the figures are not necessarily drawn to scale.

### DETAILED DESCRIPTION OF SOME EMBODIMENTS

Embodiments of the present invention are best understood by reference to the detailed figures and description set forth herein.

Embodiments of the invention are discussed below with reference to the Figures. However, those skilled in the art will readily appreciate that the detailed description given herein with respect to these figures is for explanatory purposes as the invention extends beyond these limited embodiments. For example, it should be appreciated that those skilled in the art will, in light of the teachings of the present invention, recognize a multiplicity of alternate and suitable approaches, depending upon the needs of the particular application, to implement the functionality of any given detail described herein, beyond the particular implementation choices in the following embodiments described and shown. That is, there are numerous modifications and variations of the invention that are too numerous to be listed but that all fit within the scope of the invention. Also, singular words should be read as plural and vice versa and masculine as feminine and vice versa, where appropriate, and alternative embodiments do not necessarily imply that the two are mutually exclusive.

It is to be further understood that the present invention is not limited to the particular methodology, compounds, materials, manufacturing techniques, uses, and applications, described herein, as these may vary. It is also to be understood that the terminology used herein is used for the purpose of describing particular embodiments only, and is not intended to limit the scope of the present invention. It must be noted that as used herein and in the appended claims, the singular forms “a,” “an,” and “the” include the plural reference unless the context clearly dictates otherwise. Thus, for example, a reference to “an element” is a reference to one or more elements and includes equivalents thereof known to those skilled in the art. Similarly, for another example, a reference to “a step” or “a means” is a reference to one or more steps or means and may include sub-steps and subservient means. All conjunctions used are to be understood in the most inclusive sense possible. Thus, the word “or” should be understood as having the definition of a logical “or” rather than that of a logical “exclusive or” unless the context clearly necessitates otherwise. Structures described herein are to be understood also to refer to functional equivalents of such structures. Language that may be construed to express approximation should be so understood unless the context clearly dictates otherwise.

Unless defined otherwise, all technical and scientific terms used herein have the same meanings as commonly understood by one of ordinary skill in the art to which this invention belongs. Preferred methods, techniques, devices, and materials are described, although any methods, techniques, devices, or materials similar or equivalent to those described herein may be used in the practice or testing of the present invention. Structures described herein are to be understood also to refer to functional equivalents of such structures. The present invention will now be described in detail with reference to embodiments thereof as illustrated in the accompanying drawings.

From reading the present disclosure, other variations and modifications will be apparent to persons skilled in the art. Such variations and modifications may involve equivalent and other features which are already known in the art, and which may be used instead of or in addition to features already described herein.

Although Claims have been formulated in this application to particular combinations of features, it should be understood that the scope of the disclosure of the present invention also includes any novel feature or any novel combination of features disclosed herein either explicitly or implicitly or any generalization thereof, whether or not it relates to the same invention as presently claimed in any Claim and whether or not it mitigates any or all of the same technical problems as does the present invention.

Features which are described in the context of separate embodiments may also be provided in combination in a single embodiment. Conversely, various features which are, for brevity, described in the context of a single embodiment, may also be provided separately or in any suitable subcombination. The Applicants hereby give notice that new Claims may be formulated to such features and/or combinations of such features during the prosecution of the present application or of any further application derived therefrom.

References to “one embodiment,” “an embodiment,” “example embodiment,” “various embodiments,” etc., may indicate that the embodiment(s) of the invention so described may include a particular feature, structure, or characteristic, but not every embodiment necessarily includes the particular feature, structure, or characteristic. Further, repeated use of the phrase “in one embodiment,” or “in an exemplary embodiment,” do not necessarily refer to the same embodiment, although they may.

As is well known to those skilled in the art many careful considerations and compromises typically must be made when designing for the optimal manufacture of a commercial implementation any system, and in particular, the embodiments of the present invention. A commercial implementation in accordance with the spirit and teachings of the present invention may be configured according to the needs of the particular application, whereby any aspect(s), feature(s), function(s), result(s), component(s), approach(es), or step(s) of the teachings related to any described embodiment of the present invention may be suitably omitted, included, adapted, mixed and matched, or improved and/or optimized by those skilled in the art, using their average skills and known techniques, to achieve the desired implementation that addresses the needs of the particular application.

The present invention will now be described in detail with reference to embodiments thereof as illustrated in the accompanying drawings.

There are various types of acoustic amplification devices that may be provided by preferred embodiments of the present invention. In one embodiment of the present invention, the amplification device may amplify sound waves from a portable electronic device while the two devices are joined. The portable electronic device may be oriented so that a portable electronic device speaker engages with the amplifying device. Sound waves may then emit from the portable electronic device speaker through the amplifying device. In some embodiments, the portable electronic device may orient in a substantially horizontal position when joined with the amplifying device. In this manner, the portable electronic device may rest in a wide screen position while displaying videos. Those skilled in the art, in light of the present teachings will recognize that acoustic amplification in portable electronic devices may be most desired for viewing videos, and that the horizontal, wide screen position of the portable electronic device may provide the optimal position for viewing videos.

In one embodiment of the present invention, the amplifying device may receive sound waves from the portable electronic device at a narrow end, pass the sound waves through an acoustic channel, and finally emit the sound waves out a wide, amplifying end. In this manner, the sound waves may be amplified by lowering the acoustic impedance, and matching the acoustic impedance to the ambient air. Those skilled in the art, in light of the present teachings will recognize that acoustic impedance may indicate how much sound pressure is generated by the vibration of molecules in the amplifying device at a given frequency. Mathematically, acoustic impedance may be described as the sound pressure divided by the particle velocity and the surface area, through which an acoustic wave of frequency propagates. For example, without limitation, a possible description of how the amplifying device may amplify sound waves may include the formula:

$$Z = p / vS , \\ z = \frac{p}{υ s} ,$$

where Z is acoustic impedance, p is pressure, v is particle velocity, and S is surface area inside the amplifying device. Thereby, increasing the surface area from the wide end of the amplifying device may lower the acoustic impedance, and consequently amplify the acoustics generated by the portable electronic device.

In one embodiment of the present invention, the amplifying device may include a housing for containing the components of the amplifying device. The housing may further insulate the sound waves from inefficient dispersions into the air. The housing may include a rigid exterior and an insulated interior for minimizing loss of sound waves while radiating through the amplifying device. The insulation may include, without limitation, foam, fiberglass, rubber, and wood. In some embodiments, the housing may include a sloped surface for providing a support for a power charger for the portable electronic device. The housing may further include a mounting surface for mounting the amplifying device and providing stability. In some embodiments, the amplifying device may include a slot for docking with the portable electronic device. The slot may be sized and dimensioned to receive the portable electronic device. Suitable shapes for the slot may include, without limitation, a rectangle, a square, a half moon, and an oval. The slot may include a speaker receiving portion for engaging the portable electronic device speaker. The speaker receiver portion may utilize a socket and hole operatively connected to electrical circuitry to receive the sound waves from the portable electronic device speaker. The slot may include a cord storage portion for securing a cord from the portable electronic device. In this manner, stability may be enhanced between the amplifying device and the portable electronic device.

In one embodiment of the present invention, the speaker receiver portion may include an acoustic channel that carries the sound waves through the housing, and out an amplifying portion. The amplifying portion may include a cone shape that is configured to expand outwardly, forming a wide end. Those skilled in the art, in light of the present teachings will recognize that the amplifying portion may be wider than the speaker receiving portion. A wider end for the amplifying portion may increase the surface area, thereby reducing the acoustic impedance to the sound waves. The amplifying portion may include a dispersion port. The dispersion port may include a cone shape and position inside the amplifying portion to further amplify the sound waves.

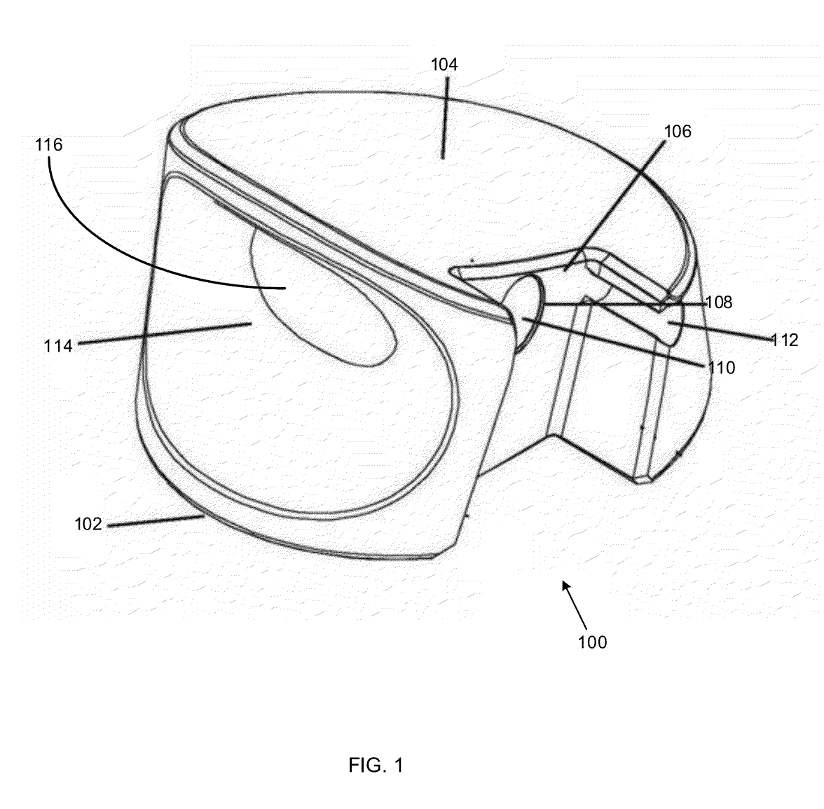

FIG. 1 illustrates a detailed perspective view of an exemplary acoustic amplifying device, in accordance with an embodiment of the present invention. In the present embodiment, the amplification device 100 may amplify sound waves that emit from a portable electronic device while the two devices are joined. The portable electronic device may be oriented so that a portable electronic device speaker engages with the amplifying device. Sound waves may then emit from the portable electronic device speaker through the amplifying device. In some embodiments, the portable electronic device may orient in a substantially horizontal position when joined with the amplifying device. In this manner, the portable electronic device may rest in a wide screen position while displaying videos. Those skilled in the art, in light of the present teachings will recognize that acoustic amplification in portable electronic devices may be most desired for viewing videos, and that the horizontal, wide screen position of the portable electronic device may provide the optimal position for viewing videos.

In one embodiment of the present invention, the amplifying device may receive sound waves from the portable electronic device at a narrow end, pass the sound waves through an acoustic channel, and finally radiate the sound waves out a wide, amplifying end. In this manner, the sound waves may be amplified by lowering the acoustic impedance, and matching the acoustic impedance to the ambient air. Those skilled in the art, in light of the present teachings will recognize that acoustic impedance may indicate how much sound pressure is generated by the vibration of molecules in the amplifying device at a given frequency. Mathematically, acoustic impedance may be described as the sound pressure divided by the particle velocity and the surface area, through which an acoustic wave of frequency propagates. For example, without limitation, a possible description of how the amplifying device may amplify sound waves may include the formula:

$$Z = p / vS , \\ z = \frac{p}{υ s} ,$$

where Z is acoustic impedance, p is pressure, v is particle velocity, and S is surface area inside the amplifying device. Thereby, increasing the surface area from the wide end of the amplifying device may lower the acoustic impedance, and consequently amplify the acoustics generated by the portable electronic device.

In one alternative embodiment, the amplifying device may utilize an acoustic enhancement system to amplify the acoustics generated by the portable electronic device. The acoustic enhancement system may include a narrow end, a channel, and a wide end. However, the acoustic enhancement system may further include interconnected microphones, amplifiers, and loudspeakers. These additional components may allow the amplifying device to augment, direct, reflect, and reverberate sound waves.

In one embodiment of the present invention, the amplifying device may include a housing 102 for containing the components and insulating the sound waves from inefficient dispersions into the air. Suitable dimensions for the housing may include, without limitation, 37.5 millimeters×23.3 millimeters. However in other embodiments, the amplifying device may be sized larger to accommodate larger portable electronic devices, or smaller for portability. The housing may include a rigid exterior. The rigid exterior may be fabricated from various materials, including, without limitation, high density polyurethane, polyvinyl chloride, plastic, metal, alloys, and rubber. The housing may further include an insulated interior for minimizing loss of sound waves while radiating through the amplifying device. The insulation may include, without limitation, foam, fiberglass, rubber, and wood. In some embodiments, the housing may include a sloped surface 104 for providing a support for a power charger for the portable electronic device. The housing may further include a mounting surface for mounting the amplifying device and providing stability. In some embodiments, the amplifying device may include a slot 106 for docking with the portable electronic device. The slot may be sized and dimensioned to receive the portable electronic device. Suitable shapes for the slot may include, without limitation, a rectangle, a square, a half moon, and an oval. The slot may include a speaker receiving portion 108 for engaging the portable electronic device speaker. The speaker receiver portion may utilize a socket and hole operatively connected to electrical circuitry to receive the sound waves from the portable electronic device speaker. The slot may include a cord storage portion 112 for securing a cord from the portable electronic device. The cord storage portion may include a groove that is sized and dimensioned to receive a power cord. In this manner, stability may be enhanced between the amplifying device and the portable electronic device. The acoustic amplifying device may be manufactured using various processes including, without limitation, injection molding, 3d printing, CNC machining, and combinations of the above.

In one embodiment of the present invention, the speaker receiver portion may include an acoustic channel 110 that carries the sound waves through the housing, and out an amplifying portion 114. In some embodiments, the acoustic channel may include an expanding tapered sound guide for creating impedance matching between the sound waves and surrounding air. The expanded tapered sound guide may be efficacious in maximizing the efficiency with which sound waves from the portable electronic device speaker transferred through the ambient air. The amplifying portion may include a cone shape that is configured to expand outwardly, terminally forming a wide end. Those skilled in the art, in light of the present teachings will recognize that the amplifying portion may be wider than the speaker receiving portion. A wider end for the amplifying portion may increase the surface area, thereby reducing the acoustic impedance to the sound waves. The amplifying portion may include a dispersion port 116. The dispersion port may include a cone shape for providing optimal sound wave dispersion. The dispersion port may position inside the amplifying portion for further amplification of the sound waves.

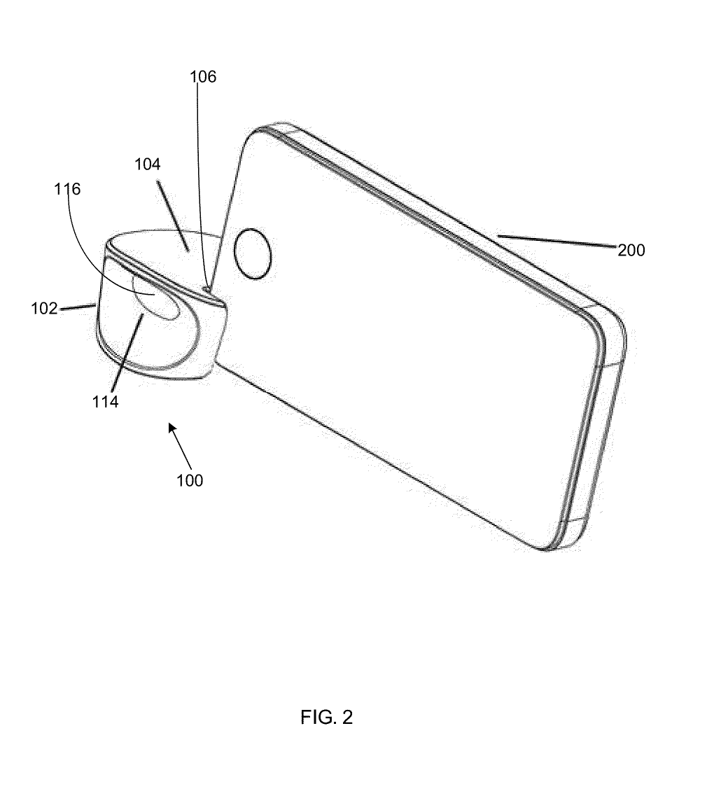

FIG. 2 illustrates a detailed perspective view of an exemplary acoustic amplifying device joined with an exemplary portable electronic device, in accordance with an embodiment of the present invention. In the present embodiment, a device 200 may join with the amplifying device so that a portable electronic device speaker engages with the amplifying device. The device may include, without limitation, a portable electronic device, a cellular phone, and a hearing aid. In some embodiments, the device may orient in a substantially horizontal position when joined with the amplifying device. In this manner, the device may rest in a wide screen position while displaying videos. Those skilled in the art, in light of the present teachings, will recognize that acoustic amplification in portable electronic devices may be most desired for viewing videos, and that the horizontal, wide screen position of the portable electronic device may provide the optimal position for viewing videos.

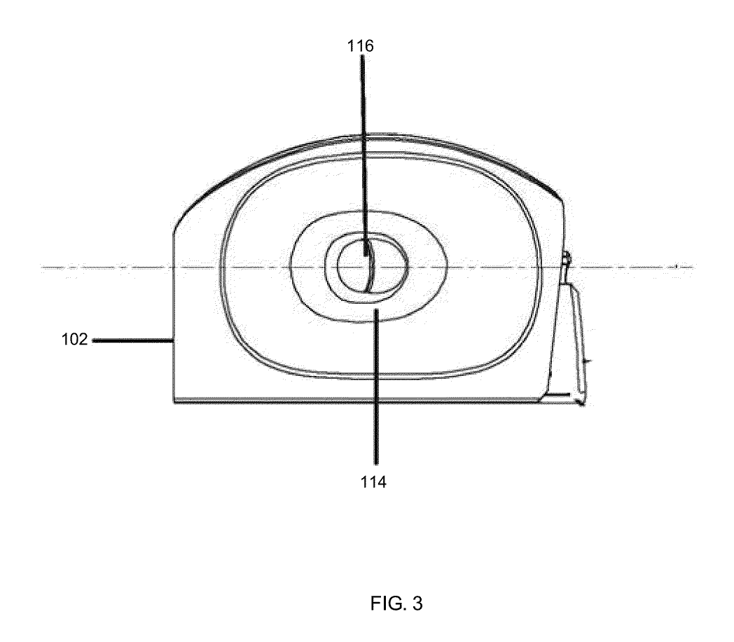

FIG. 3 illustrates a sectioned side view of an exemplary amplifying portion, in accordance with an embodiment of the present invention. In the present embodiment, the speaker receiver portion may include an acoustic channel that carries the sound waves through the housing, and out an amplifying portion. The amplifying portion may include a cone shape that is configured to expand outwardly, forming a wide end. Those skilled in the art, in light of the present teachings will recognize that the amplifying portion may be wider than the speaker receiving portion. A wider end for the amplifying portion may increase the surface area, thereby reducing the acoustic impedance to the sound waves. The amplifying portion may include a dispersion port. The dispersion port may include a cone shape for providing optimal sound wave dispersion. The dispersion port may position inside the amplifying portion to further amplify the sound waves.

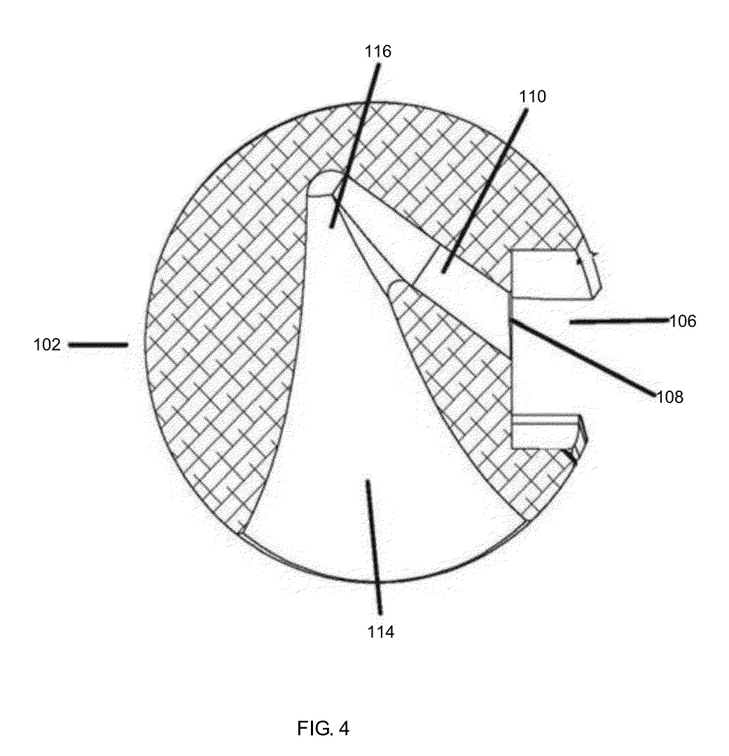

FIG. 4 illustrates a sectioned top view of an exemplary acoustic amplifying device, in accordance with an embodiment of the present invention. In the present embodiment, the acoustic amplifying device may provide portability by being sized and dimensioned smaller than the portable electronic device.

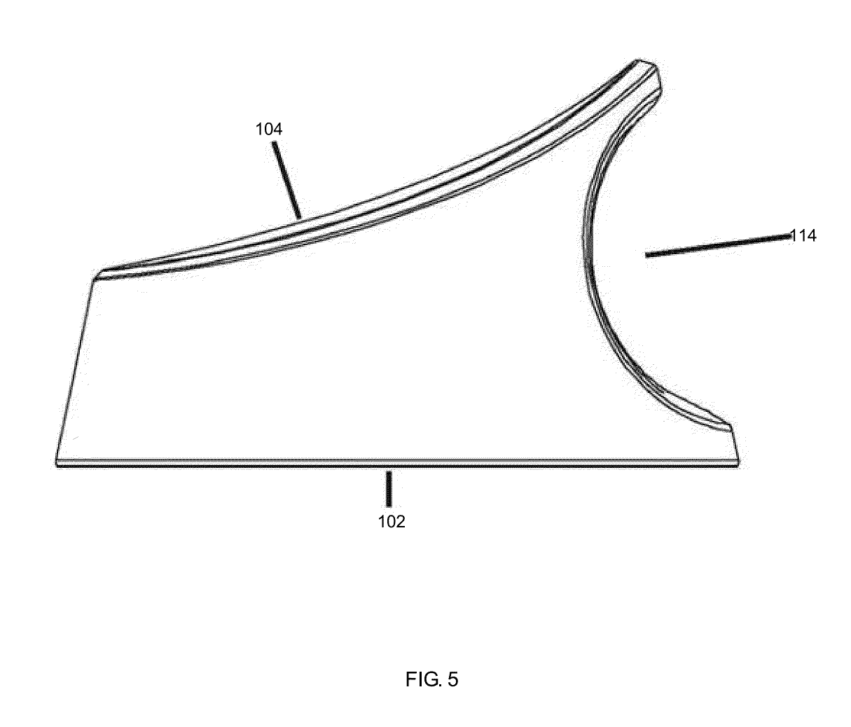

FIG. 5 illustrates a side view of an exemplary acoustic amplifying device, in accordance with an embodiment of the present invention. In the present embodiment, one mode of operation may require first placing the amplifying device on a surface. The portable electronic device may then be inserted into the slot in a horizontal widescreen orientation. In this manner, the portable electronic device may rest upon the housing. In yet another mode of operation, the portable electronic device may dock into the slot prior to being placed on a surface. In yet another mode of operation, the portable electronic device may rest flat on the surface, and the slot moves to dock towards the portable electronic device speaker.

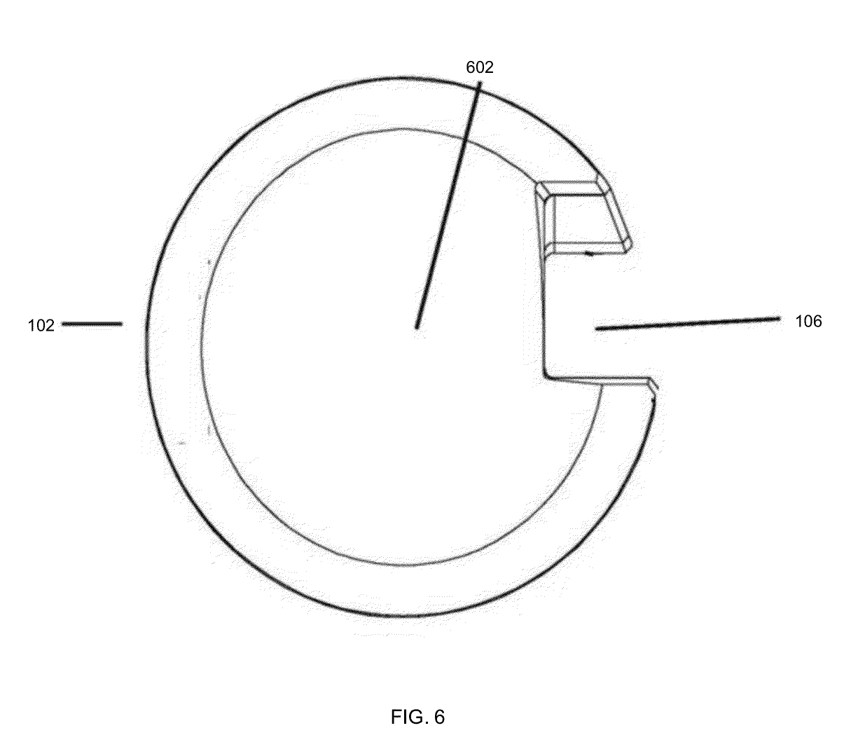

FIG. 6 illustrates a bottom view of an exemplary mounting surface, in accordance with an embodiment of the present invention. In the present embodiment, the mounting surface 602 may include a flat surface for resting the amplifying device in a flat, substantially horizontal plane. However, in other embodiments, the mounting surface may include, without limitation, a dish shape, a curved shape, and a tripod. Those skilled in the art, in light of the present teachings will recognize that viewing a video on the portable electronic device may be enhanced by a level display. In one alternative embodiment, the mounting surface may include an adhesive for fastening the amplifying device onto the surface. In this manner, the amplifying device may be secured onto a vertical or sloping surface, including, without limitation, a wall, a ceiling, and a vehicle component.

All the features or embodiment components disclosed in this specification, including any accompanying abstract and drawings, unless expressly stated otherwise, may be replaced by alternative features or components serving the same, equivalent or similar purpose as known by those skilled in the art to achieve the same, equivalent, suitable, or similar results by such alternative feature(s) or component(s) providing a similar function by virtue of their having known suitable properties for the intended purpose. Thus, unless expressly stated otherwise, each feature disclosed is one example only of a generic series of equivalent, or suitable, or similar features known or knowable to those skilled in the art without requiring undue experimentation.

Having fully described at least one embodiment of the present invention, other equivalent or alternative methods of implementing an acoustic amplifier for portable electronic devices according to the present invention will be apparent to those skilled in the art. Various aspects of the invention have been described above by way of illustration, and the specific embodiments disclosed are not intended to limit the invention to the particular forms disclosed. The particular implementation of the acoustic amplifier for portable electronic devices may vary depending upon the particular context or application. By way of example, and not limitation, the acoustic amplifier for portable electronic devices described in the foregoing were principally directed to smart phones that played videos and needed sound amplifications implementations; however, similar techniques may instead be applied to hearing aids for people hard of hearing, which implementations of the present invention are contemplated as within the scope of the present invention. The invention is thus to cover all modifications, equivalents, and alternatives falling within the spirit and scope of the following claims. It is to be further understood that not all of the disclosed embodiments in the foregoing specification will necessarily satisfy or achieve each of the objects, advantages, or improvements described in the foregoing specification.

Claim elements and steps herein may have been numbered and/or lettered solely as an aid in readability and understanding. Any such numbering and lettering in itself is not intended to and should not be taken to indicate the ordering of elements and/or steps in the claims.

What is claimed is:

1. An amplifying device comprising:
a housing, said housing being configured to contain said amplifying device, said housing further comprising a mounting surface, said mounting surface being configured to support said amplifying device;
a slot, said slot being configured to receive a device, said slot comprising a speaker receiving portion, said speaker receiving portion being configured to be operable to receive sound waves emitted from said device when sufficiently engaged into said slot;
an acoustic channel, said acoustic channel being configured to be operable to carry said sound waves;
a dispersion port, said dispersion port being configured to be operable to, at least in part, help condition said sound waves for improved user listening acoustics; and
an amplifying portion, said amplifying portion being configured to be operable to emit said conditioned sound waves.

2. The amplifying device of claim 1, wherein said device is configured to be oriented in a substantially horizontal position when joined with said amplifying device.

3. The amplifying device of claim 1, in which said slot further comprises a cord storage portion, said cord storage portion being configured to store a cord.

4. The amplifying device of claim 1, in which said housing further comprises an said a sloped surface.

5. The amplifying device of claim 4, wherein said sloped surface is operable to support a portable electronic device charger.

6. The amplifying device of claim 5, in which said sloped surface comprises an adhesive.

7. The amplifying device of claim 6, in which said slot comprises a rectangular shape.

8. The amplifying device of claim 7, wherein said cord joins with said device.

9. The amplifying device of claim 8, wherein said cord collapses inside said cord storage portion.

10. The amplifying device of claim 9, in which said device comprises a portable electronic device, said portable electronic device comprising a cellular phone.

11. The amplifying device of claim 10, in which said device comprises a speaker.

12. The amplifying device of claim 11, wherein said speaker receiver portion engages said speaker.

13. The amplifying device of claim 12, wherein said acoustic channel is configured to extend between said speaker receiving portion and said amplifying portion.

14. The amplifying device of claim 13, in which said acoustic channel comprises an expanding tapered sound guide, said expanding tapered sound guide being configured to create impedance matching between said sound waves and surrounding air.

15. The amplifying device of claim 14, in which said dispersion port comprises a cone shape.

16. The amplifying device of claim 15, wherein said dispersion port is operable to provide optimal sound wave dispersion.

17. The amplifying device of claim 16, wherein said amplifying portion is configured to be wider than said speaker receiving portion.

18. The amplifying device of claim 17, wherein said amplifying portion is configured to attach to ear buds.

19. An amplifying device comprising:
means for powering a device;
means for generating sound waves;
means for joining said device with said amplifying device;
means for emitting said sound waves through a speaker receiving portion;
means for carrying said sound waves through an acoustic channel;
means for optimizing said sound waves with a dispersion port;
means for emitting said sound waves from an amplifying portion; and
means for amplifying said sound waves.

20. An amplifying device comprising of:
a housing, said housing being configured to contain said amplifying device, said housing comprising a sloped surface, said housing further comprising a mounting surface, said mounting surface being configured to support said amplifying device, said mounting surface comprising an adhesive, said housing further comprising insulation;
a slot, said slot being configured to receive a device, said device comprising a portable electronic device, said slot comprising a rectangular shape, said slot comprising a speaker receiving portion, said speaker receiving portion being configured to engage a speaker, said slot further comprising a cord storage portion, said cord storage portion being configured to store a cord, said cord being configured to collapse inside said cord storage portion;
an acoustic channel, said acoustic channel being configured to be operable to carry sound waves, said acoustic channel comprising an expanding tapered sound guide, said expanding tapered sound guide being configured to create impedance matching between said sound waves and surrounding air;
a dispersion port, said dispersion port being configured to be operable to help optimize said sound waves, said dispersion port comprising a cone shape; and
an amplifying portion, said amplifying portion being configured to be operable to emit said sound waves, said amplifying portion being configured to extend between said speaker receiving portion and said amplifying portion, said amplifying portion being configured to be wider than said speaker receiving portion, said amplifying portion being configured to receive an ear bud.
